(19) United States
(12) Patent Application Publication
(10) Pub. No.: US 2017/0263796 A1
(43) Pub. Date: Sep. 14, 2017

(54) Encapsulated Solar Cells that Incorporate Structures that Totally Internally Reflect Light Away from Front Contacts and Related Manufacturing Methods

(71) Applicant: California Institute of Technology, Pasadena, CA (US)

(72) Inventor: Phillip R. Jahelka, Pasadena, CA (US)

(73) Assignee: California Institute of Technology, Pasadena, CA (US)

(21) Appl. No.: 15/453,867

(22) Filed: Mar. 8, 2017

Related U.S. Application Data
(60) Provisional application No. 62/305,665, filed on Mar. 9, 2016.
(60) Provisional application No. 62/327,515, filed on Apr. 26, 2016.

(51) Int. Cl. H01L 31/054; H01L 31/02; H01L 31/0203; H01L 31/18; H01L 31/0232; H01L 31/0216

(52) U.S. Cl. CPC H01L 31/0547; H01L 31/02327; H01L 31/02167; H01L 31/0203; H01L 31/186; H01L 31/02008

(57) ABSTRACT

Solar cells in accordance with a number of embodiments of the invention are encapsulated by a material that can render the front contacts of the solar cells effectively invisible at certain angles of incidence. Front contacts of a solar cell provide a way for current to escape from the solar cell. However, these front contacts cover portions of the photoabsorbing substrate, blocking incident light that could otherwise be utilized by the photoabsorbing substrate for electrical power generation. By encapsulating the solar cell and using encapsulated volumes above the front contact that define interfaces, light reaching the interface can be refracted due to the different refractive indices of the two media. Depending on the refractive index ratio, total internal reflection can occur at certain angles of incidence. Totally internally reflected light can be redirected away from the front contacts and onto the photoabsorbing substrate, thereby reducing optical waste.

### CROSS-REFERENCE TO RELATED APPLICATIONS

The current application claims the benefit of and priority under 35 U.S.C. §119(e) to U.S. Provisional Patent Application No. 62/305,665 entitled “Encapsulation for Solar Cells Minimizes Contact Grid Losses” filed Mar. 9, 2016, and U.S. Provisional Patent Application No. 62/327,515 entitled “Encapsulation for Solar Cells Minimizes Contact Grid Losses” filed Apr. 26, 2016. The disclosures of U.S. Provisional Patent Application Nos. 62/305,665 and 62/327,515 are hereby incorporated by reference in its entirety for all purposes.

### FIELD OF THE INVENTION

The present invention generally relates to solar cells and, more specifically, encapsulated solar cells that use total internal reflection to direct light within the encapsulant away from front contacts and toward active regions of the solar cell.

### BACKGROUND

Photovoltaics refer to a class of methods for converting light into electricity using the photovoltaic effect. Due to technological advances in recent years, photovoltaics are becoming a more viable, carbon-free source of electricity generation. A photovoltaic system typically employs an array of solar cells to generate electrical power. Solar cells can be made of a variety of semiconductors, typically a silicon based structure, acting as a substrate and can include front and rear contacts that are used to conduct current out of the solar cell. The conversion process involves the absorption of light rays by what can be referred to as the active region of the solar cell, which can excite electrons in the substrate into a higher state of energy. The excitation allows the electrons to move as an electric current that can then be extracted to an external circuit and stored.

### SUMMARY OF THE INVENTION

Solar cells in accordance with a number of embodiments of the invention are encapsulated by a material that can render the front contacts of the solar cells effectively invisible at certain angles of incidence. Front contacts of a solar cell provide a way for current to escape from the solar cell. However, these front contacts cover portions of the photoabsorbing substrate, blocking incident light that could otherwise be utilized by the photoabsorbing substrate for electrical power generation. By encapsulating the solar cell and leaving a cavity above the front contact, light reaching the encapsulant-cavity interface can be refracted due to the different refractive indices of the two media. Depending on the refractive index ratio, total internal reflection can occur at certain angles of incidence. Totally internally reflected light can be redirected away from the front contacts and onto the photoabsorbing substrate, thereby reducing optical waste.

One embodiment of the invention is an encapsulated solar cell including a photoabsorbing substrate, a plurality of contacts formed on a front surface of the photoabsorbing substrate, and an encapsulant layer including an outer surface and an inner surface defining a plurality of cavities, wherein the encapsulant layer is attached to the front surface of the photoabsorbing substrate so that the inner surface of the encapsulant layer is located between the front surface of the photoabsorbing substrate and the outer surface of the encapsulant layer, the plurality of cavities defined by the inner surface of the encapsulant layer encapsulates a plurality of volumes between the inner surface of the encapsulant layer and the front surface of the photoabsorbing substrate, and at least one of the encapsulated plurality of volumes is positioned to direct light within the encapsulant layer away from at least one of the plurality of contacts using refraction, and the refractive index of the encapsulant layer is greater than the refractive index of at least one of the encapsulated plurality of volumes.

In another embodiment, the encapsulant layer is made from at least one material selected from the group consisting of: polydimethylsiloxane; and ethylene-vinyl acetate.

In a further embodiment, the encapsulant layer is attached to the front surface of the photoabsorbing substrate using an intermediary passivation layer such that the intermediary passivation layer covers the photoabsorbing substrate and the plurality of contacts.

In still another embodiment, the intermediary passivation layer is made from at least one material selected from the group consisting of polydimethylsiloxane, polymethylmethacrylate, and ethylene-vinyl acetate.

In a still further embodiment, the encapsulated plurality of volumes comprises a gas.

In yet another embodiment, the encapsulated plurality of volumes comprises an infill material.

In a yet further embodiment, the infill material is made from at least one material selected from the group consisting of polydimethylsiloxane, polymethylmethacrylate, and ethylene-vinyl acetate.

In another additional embodiment, each of the encapsulated plurality of volumes has a triangular cross section having a height h and a width w.

In a further additional embodiment, the refractive index of the encapsulant layer is n and the refractive index of the encapsulated volume is m such that

$$\frac{n}{m} \geq \sqrt{2} .$$

In another embodiment again, the height h and the width w of the triangular cross section is such that:

$$\frac{h}{w} \geq \frac{1}{2 \sqrt{{( \frac{n}{m} )}^{2} - 1}} .$$

A further embodiment again of the invention is a method for manufacturing an encapsulated solar cell, the method including providing a solar cell including a photoabsorbing substrate and a plurality of contacts formed on the photoabsorbing substrate, fabricating an encapsulant layer including an outer surface and an inner surface defining a plurality of cavities, and attaching the encapsulant layer to the solar cell, wherein the inner surface of the encapsulant layer is located between the front surface of the photoabsorbing substrate and the outer surface of the encapsulant layer, the plurality of cavities defined by the inner surface of the encapsulant layer encapsulates a plurality of volumes between the inner surface of the encapsulant layer and the front surface of the photoabsorbing substrate, at least one of the encapsulated plurality of volumes is positioned to direct light within the encapsulant layer away from at least one of the plurality of contacts using refraction, and the refractive index of the encapsulant layer is greater than the refractive index of at least one of the encapsulated plurality of volumes.

In still yet another embodiment, the encapsulant layer is made from at least one material selected from the group consisting of: polydimethylsiloxane; and ethylene-vinyl acetate.

In a still yet further embodiment, the encapsulant layer is attached to the front surface of the photoabsorbing substrate using an intermediary passivation layer such that the intermediary passivation layer covers the photoabsorbing substrate and the plurality of contacts.

In still another additional embodiment, the intermediary passivation layer is made from at least one material selected from the group consisting of polydimethylsiloxane, polymethylmethacrylate, and ethylene-vinyl acetate.

In a still further additional embodiment, the encapsulated plurality of volumes comprises a gas.

In still another embodiment again, the encapsulated plurality of volumes comprises an infill material.

In a still further embodiment again, the infill material is made from at least one material selected from the group consisting of polydimethylsiloxane, polymethylmethacrylate, and ethylene-vinyl acetate.

In yet another additional embodiment, each of the encapsulated plurality of volumes has a triangular cross section having a height h and a width w.

In a yet further additional embodiment, the refractive index of the encapsulant layer is n and the refractive index of the encapsulated volume is m such that

$$\frac{n}{m} \geq \sqrt{2} .$$

In yet another embodiment again, the height h and the width w of the triangular cross section is such that:

$$\frac{h}{w} \geq \frac{1}{2 \sqrt{{( \frac{n}{m} )}^{2} - 1}} .$$

Additional embodiments and features are set forth in part in the description that follows, and in part will become apparent to those skilled in the art upon examination of the specification or may be learned by the practice of the invention. A further understanding of the nature and advantages of the present invention may be realized by reference to the remaining portions of the specification and the drawings, which forms a part of this disclosure.

### BRIEF DESCRIPTION OF THE DRAWINGS

The description and claims will be more fully understood with reference to the following figures and data graphs, which are presented as exemplary embodiments of the invention and should not be construed as a complete recitation of the scope of the invention.

FIG. 1 conceptually illustrates incident light reflected by a metal contact of a conventional solar cell.

FIG. 2 conceptually illustrates the underlying optics of encapsulated volumes in accordance with an embodiment of the invention.

FIG. 3 conceptually illustrates incident light refraction caused by an encapsulant layer in accordance with an embodiment of the invention.

FIGS. 4A-4B conceptually illustrates encapsulated solar cells with encapsulated volumes with different cross-section geometries in accordance with various embodiments of the invention.

FIG. 5 is a flow chart conceptually showing a method of manufacturing an encapsulated solar cell in accordance with an embodiment of the invention.

FIGS. 6A-6D conceptually illustrate a process of fabricating an encapsulant layer and attaching the encapsulant layer to a solar cell in accordance with an embodiment of the invention.

FIG. 7 conceptually illustrates an encapsulated solar cell with a passivation layer in accordance with an embodiment of the invention.

FIGS. 8A-8B conceptually illustrates a process of constructing an encapsulated solar cell with an infill material in accordance with an embodiment of the invention.

FIGS. 9A-9C conceptually illustrates a process of constructing an encapsulated solar cell using a sacrificial structure in accordance with an embodiment of the invention.

### DETAILED DESCRIPTION

Turning now to the drawings, encapsulated solar cells that use total internal reflection to direct light within the encapsulant away from front contacts and toward active regions of the solar cell and related methods of manufacturing are illustrated. In accordance with many embodiments of the invention, an encapsulated solar cell can be manufactured and engineered to redirect incident light away from the front contacts of the solar cell and onto the photoabsorbing substrate at some or all angles of incidence. Encapsulated solar cells in accordance with several embodiments of the invention include an encapsulant layer covering a solar cell. The encapsulant layer can be made of an optically transparent material to allow light rays to reach the photoabsorbing substrate with minimal scattering. In some embodiments, the encapsulant layer contains a negative relief pattern that spatially corresponds to the contacts of the solar cell. The encapsulant layer can be aligned and attached to the solar cell in a way such that the negative relief pattern encapsulates a volume on top of each of the contacts. In several embodiments, the encapsulant layer can be applied to a layer of infill material formed on the photoabsorbing substrate so that the infill material fills the encapsulated volumes formed by the application of the encapsulant layer. In many embodiments, a negative relief pattern is created by forming a sacrificial structure on the contacts of a photoabsorbing substrate, applying an encapsulant layer over the photoabsorbing substrate and contacts, and then removing the sacrificial structure. In further embodiments, the sacrificial structure can be dissolved using a solvent. As can readily be appreciated, any process that removes the sacrificial structure to create encapsulated volumes that are voids within the encapsulant layer can be utilized as appropriate to the requirements of a given application in accordance with various embodiments of the invention. In a number of embodiments, the encapsulated volumes have triangular cross sections. In other embodiments, any of a variety of cross sectional geometries appropriate to the requirements of a given application can be utilized. Encapsulated solar cells that use total internal reflection to direct light within the encapsulant away from front contacts and toward active regions of the solar cell and methods of manufacturing encapsulated solar cells in accordance with various embodiments of the invention are discussed further below.

### Optical Waste in Conventional Solar Cells

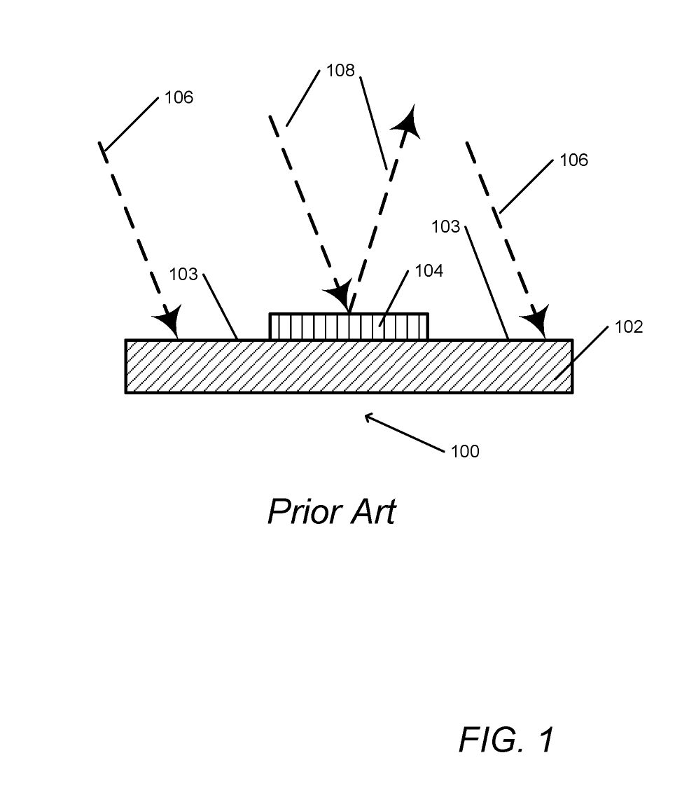

A conventional solar cell typically includes a photoabsorbing substrate for harvesting light rays and front and rear contacts for conducting current out of the solar cell. To maximize the amount of light harvested, a conventional solar is normally oriented such that the front contacts face the light source directly. In this orientation, the front contacts can inherently cover areas of the photoabsorbing substrate, blocking a non-negligible amount of incident light that could otherwise be utilized by the active area of the photoabsorbing substrate. FIG. 1 conceptually illustrates the behavior of incident light interacting with a conventional solar cell. The illustrated solar cell 100 includes a photoabsorbing substrate 102 including an active area 103 and a front contact 104. In a configuration such as this, only light rays incident on the active area 103 of the photoabsorbing substrate are capable of being utilized for electrical power generation. As shown, light rays 106 hitting the active area 103 of the photoabsorbing substrate 102 are absorbed and utilized for electrical power generation while the light ray 108 incident on the front contact 106 is reflected and/or absorbed as heat. If not for the front contact 106, the light ray 108 incident on the front contact 106 would have been incident on an active area 103 of the photoabsorbing substrate 102. As such, light ray 108 does not contribute to the electrical power generation and is, in a sense, effectively wasted.

### Refraction of Incident Light in Encapsulated Solar Cells

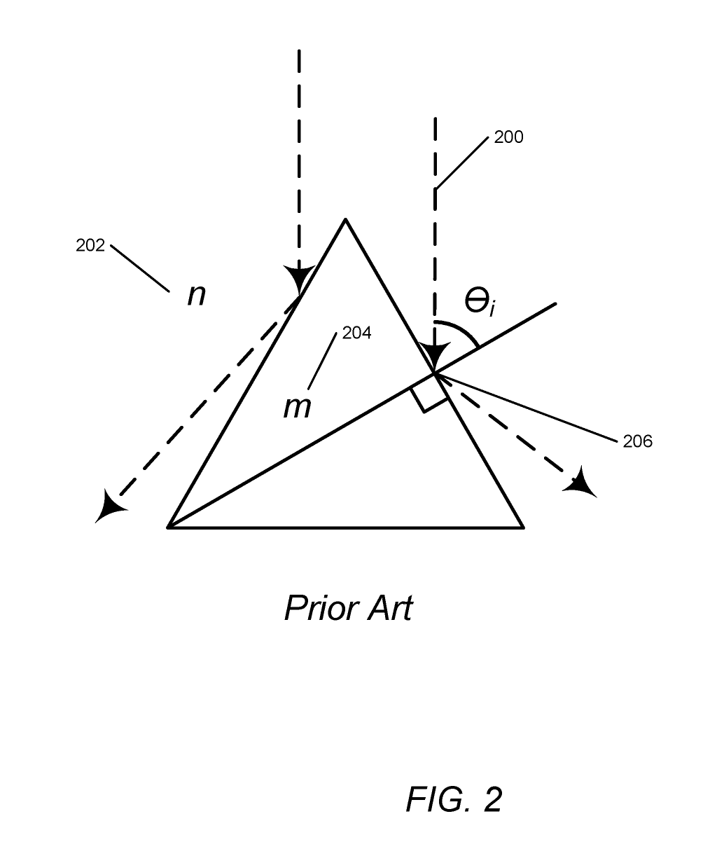

Encapsulated solar cells in accordance with many embodiments of the invention utilize refraction to reduce or eliminate optical waste in solar cells. Refraction refers to the bending of the path of a wave as the wave passes through the interface between two different transmission media. The extent of the bending, which can be expressed as the angle of refraction, is dependent on the refractive index of each medium and the angle of incidence, which is defined as the angle that the wave makes with the normal of the interface. In cases where the refractive index of the originating medium is higher than the terminating medium, there exists a set of angles of incidence wherein the wave is refracted back into the originating medium, a phenomenon known as total internal reflection. FIG. 2 conceptually illustrates total internal reflection of light rays incident on a triangular geometric object. As shown, light ray 200 travels through an originating medium 202 having a refractive index n₁ and strikes the boundary of a terminating medium 204 having a refractive index n₂ at an angle of incidence θᵢ. If n differs from m, refraction can occur for non-normal angles of incidence. Furthermore, if n>m, total internal reflection can occur at certain angles of incidence. In FIG. 2, angle θᵢ is one of such angles. Thus, light ray 200 is reflected back into the originating medium 202, never passing through the interface 206 of the two media 202, 204.

Although FIG. 2 illustrates exemplary concepts utilizing a triangular geometry, a person having ordinary skill in the art would understand that the principle of refraction is not limited by the geometry and composition of the mediums and that any other geometric shape or composition can be utilized as appropriate to the requirements of specific applications in accordance with embodiments of the invention.

In accordance with many embodiments of the invention, an encapsulated solar cell can be constructed by attaching an encapsulant layer to a conventional solar cell. In some embodiments, encapsulated volumes are formed between the encapsulant layer and the front contacts of the solar cell. The encapsulated volumes can be voids or filled with material. The encapsulated volumes include interfaces with the encapsulant layer that are configured so that total internal reflection occurs at the interface for a set of angles of incidence, directing light away from the front contacts toward an active area of the photoabsorbing substrate.

In a number of embodiments, the encapsulated volumes are formed by a negative relief pattern in the encapsulant involving cavities that spatially correspond to the front contacts of the solar cell. The encapsulant layer can be aligned and attached to the solar cell in a way such that the cavities encapsulate volumes over the front contacts of the solar cell. As such, the patterned cavities can intrinsically determine the geometry and position of the encapsulated volumes. In further embodiments, the patterned cavities are designed and positioned such that the formed encapsulated volumes will totally internally reflect light incident on the interface between the encapsulated volume and the encapsulant layer. In this way, the total internal reflection redirects light that would have been incident on the front contacts in the absence of the encapsulated volume. The redirected light is directed toward an active area of the photoabsorbing substrate and can be converted to electric current. Under certain conditions, the light rays can be refracted, or totally internally reflected, back into the encapsulant layer and toward an active area of the photoabsorbing substrate. Depending on the refractive index ratio, which can be defined as the refractive index of the encapsulant layer over the refractive index of the encapsulated volume, optical efficiency can be increased relative to a conventional solar cell that does not include encapsulated volumes for both normal and oblique angles of incidence. Increases in efficiency that can be achieved through the use of encapsulated volumes within a solar cell to totally internally reflect incident light onto active areas of a photoabsorbing substrate in accordance with various embodiments of the invention are discussed further below.

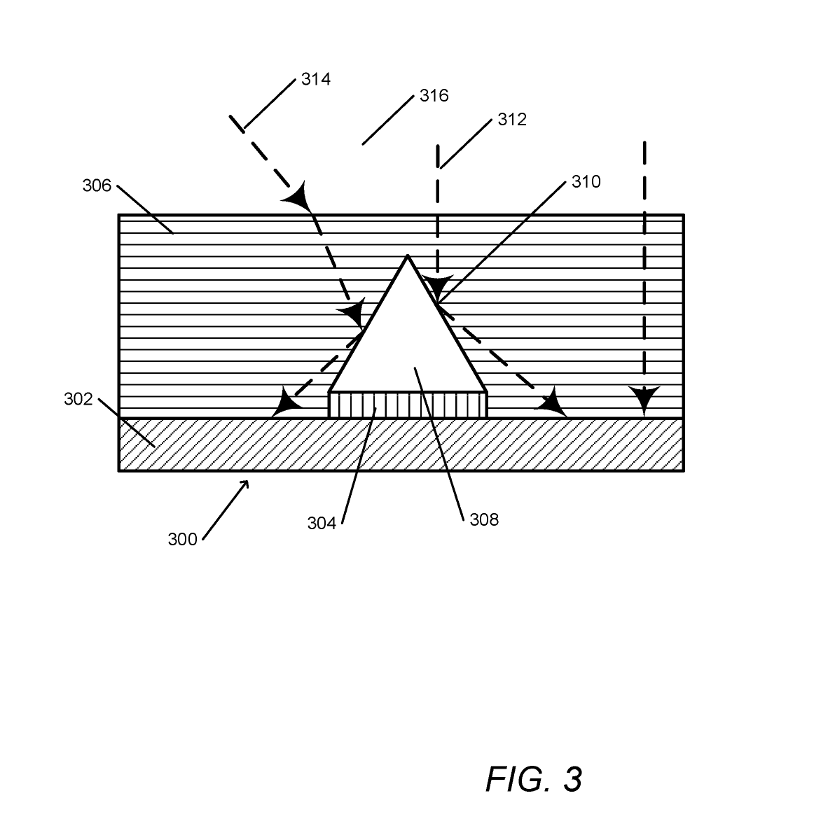

A practical application of refraction in an encapsulated solar cell in accordance with an embodiment of the invention is illustrated in FIG. 3. As shown, a conventional solar cell 300 having a photoabsorbing substrate 302 and a front contact 304 can be covered by an encapsulant layer 306. The encapsulant layer 306 can contain at least one cavity that encapsulates a volume 308 when attached to the solar cell 300. The encapsulant layer 306 can be aligned and attached with the patterned side against the photoabsorbing substrate in a way such that an encapsulated volume 308 is created over at least a portion of the front contact 304. The encapsulated volume 308 can be positioned to create an interface upon which light directed toward the front contact 404 is incident. In the illustrated embodiment, the encapsulated volume 308 contains a triangular cross section. The triangular geometry allows for light rays normally incident on the front contacts to strike the encapsulant layer-encapsulated volume interface 310 at a non-normal angle, which allows for refraction and total internal reflection. For instance, as illustrated in FIG. 3, light ray 312 would have been incident on the front contact 308 at a normal angle. However, because of the triangular cross section, the sides of the triangle are at an angular offset with the surface of the front contact 304. Consequently, light ray 312 strikes the encapsulant layer-encapsulated volume interface 310 at a non-normal angle. When this happens, refraction and/or total internal reflection can occur depending on the refractive index ratio of the encapsulant layer 306 and the encapsulated volume 308.

For light rays that are not incident on the front contact 308 at a normal angle, refraction can occur twice under some circumstances. Assuming the encapsulant layer is of a uniform thickness, light rays that are not incident on the front contact 304 at a normal angle will also not be incident on the surface of the encapsulant layer 306 at a normal angle. For example, light ray 314 strikes the surface of the encapsulant layer 306 and is refracted upon entry due to its non-normal angle of incidence and the difference in the refractive indices of the atmosphere 316 (or vacuum in space applications) and the encapsulant layer 306. After entering the encapsulant layer 306, light ray 314 continues on its refracted path and strikes the encapsulant layer-encapsulated volume interface 310 and is once again refracted, or totally internally reflected, onto the photoabsorbing substrate 302.

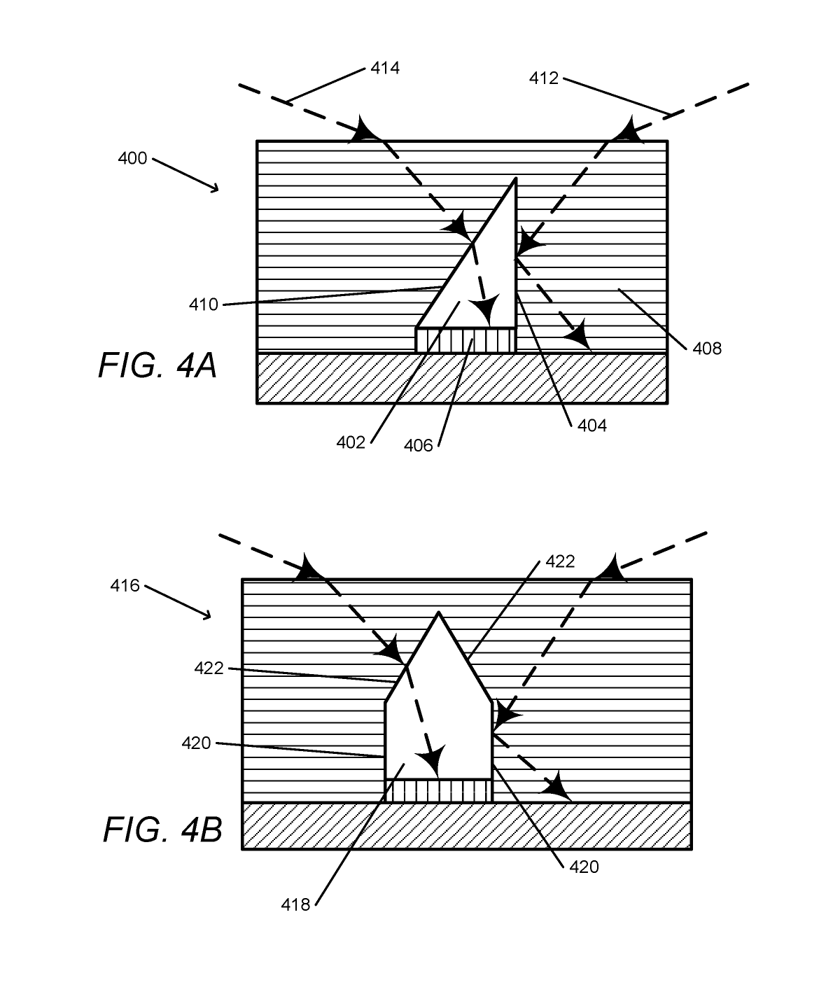

Although FIG. 3 illustrates exemplary concepts and embodiments utilizing a triangular geometry and specific construction, a person having ordinary skill in the art would understand that the principle of refraction is not limited by the geometry and composition of the mediums and that any other geometric shape or composition can be utilized as appropriate to the requirements of specific applications in accordance with embodiments of the invention. For example, an embodiment in accordance with the invention can utilize encapsulated volumes with a different cross sectional geometry to achieve different results. In many embodiments, the cross sectional geometry is chosen for the slopes of the sides relative to the front contact. Light will typically be incident at a more oblique angle on a side with a higher slope, which can result in a lower refractive index ratio (defined as the refractive index of the encapsulant layer over the refractive index of the encapsulated volume) threshold required for total internal reflection to occur. Two examples of encapsulated solar cells utilizing different geometries are illustrated in FIGS. 4A and 4B. FIG. 4A illustrates an encapsulated solar cell 400 with an encapsulated volume 402 having a right triangular cross section, also known as a sawtooth pattern. Inherently, the right triangular cross section can have a side 404 that is normal to the front contact 406. In some embodiments, the material compositions of the encapsulant layer 408 and the encapsulated volume 402 can be selected so that all light incident on the perpendicular side 404 will totally internally reflect. The other side 410, however, will typically have a lower slope and, consequently, can perform worse at totally internally reflecting incident light than the sides of an isosceles triangular cross section of similar height and width. Light ray 412 and light ray 414 depicts these differences. As shown, light ray 412 is incident on the side 404 normal to the front contact 406 and is totally internally reflected. Light ray 414, however, is incident on the other side 410 and total internal reflection fails for that angle of incidence. Another geometric cross section that can be utilized in encapsulated solar cells is shown in FIG. 4B. The encapsulated solar cell 416 includes an encapsulated volume 418 having a house-shaped pentagonal cross section. This geometry produces a cross section with two sides 420 perpendicular to the front contacts. With a high enough refractive index ratio, light incident on the two sides 420 can be totally internally reflected. The remaining two sides 422 can behave similar to the triangular geometries discussed above. However, the slopes of these remaining two sides 422 will typically have a lower slope compared to the sides of a triangular cross section of similar height and width.

### Encapsulated Volumes

Encapsulated volumes can have a cross section with a variety of geometric shapes. In many embodiments, the encapsulated volumes contain triangular cross sections. The triangular cross sections can be one of any triangular geometry, such as but not limited to equilateral triangles, isosceles triangles, right triangles, and scalene triangles.

Different triangles can determine different characteristics of the encapsulated solar cell. One of the key attributes in determining the performance of a specific shape lies in the slopes of the sides relative to the surface of the front contacts. For a side with a large slope, incident light will more likely strike the side at an oblique angle of incidence. For example, right triangles can be incorporated such that total internal reflection occurs for all light incident on one side of the triangle (the side normal to the front contact). However, under this configuration, achieving total internal reflection with the other exposed side of the right triangle (the side that is not normal to the contact) could be more difficult compared to an isosceles triangle of similar height and width due to the inherent slope differences.

An isosceles triangle is one of the simplest shapes in which the dimensions can easily be manipulated to achieve total internal reflection at certain angles of incidence. For example, given an encapsulant layer having a refractive index n and an encapsulated volume having a refractive index m, the isosceles triangle can be constructed such that the dimensions of the triangle (height h and width w) create a slope where incident light normal to the surface of the front contacts will totally internally reflect off the encapsulant layer-encapsulated volume interface. The relationship between the refractive indices and the minimum aspect ratio of the triangle for this to work can be given by the following relationship:

$$\frac{2 h}{w} \geq tan [ {arcsin ( \frac{n}{m} )}^{- 1} ]$$

Or, alternatively,

$$\frac{h}{w} \geq \frac{1}{2 \sqrt{{( \frac{n}{m} )}^{2} - 1}} .$$

This analysis generalizes to the slopes of all shapes, including the other triangles listed above. Although encapsulated volumes containing triangular cross sections are specifically discussed, any other geometric shapes such as but not limited to a house-shaped pentagonal cross section can be utilized as appropriate to the requirements of total internal reflection.

### Construction of Encapsulated Solar Cells

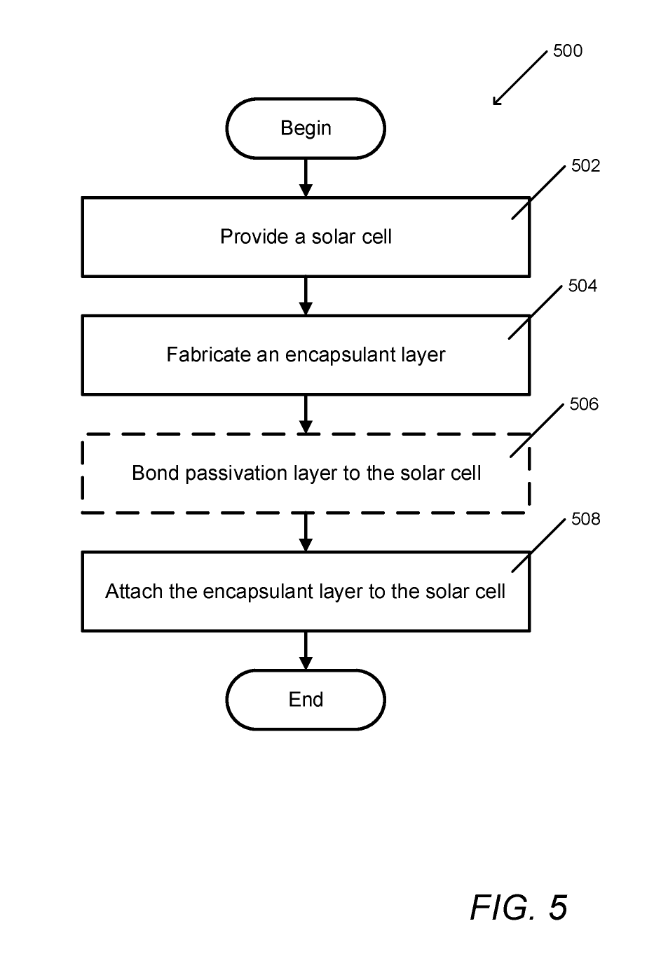

In accordance with many embodiments of the invention, an encapsulated solar cell can be constructed using a variety of methods. A method for constructing an encapsulated solar cell in accordance with an embodiment of the invention is illustrated in FIG. 5. Process 500 includes providing (502) a solar cell. In a number of embodiments, the solar cell is a conventional solar cell with front and rear contacts. The size of the contacts can vary and can depend on current or future standards of solar cell construction.

An encapsulant layer can be fabricated (504) using a variety of methods. In many embodiments, the encapsulant layer can be fabricated with a negative relief pattern of cavities that spatially correspond to the front contacts of the solar cell. The encapsulant layer can be made of any one of a variety of materials such as but not limited to polydimethylsiloxane (PDMS), polymethylmethacrylate (PMMA), and ethylene-vinyl acetate (EVA). The type of material can be chosen for a variety of factors such as but not limited to optical transparency, refractive index, ease and cost of fabrication, chemical inertness, adhesive properties, gas permeability and/or any other requirement appropriate to the requirements of a given application.

The choice of method used to fabricate the encapsulant layer can be determined by the feature size of the contacts of the solar cell, the fabrication materials, and/or any of a variety of other factors. In many embodiments, an encapsulant layer is fabricated through mold casting. Mold casting can be used to fabricate encapsulant layers made of any one of a variety of resin polymers such as but not limited to PDMS, PMMA, and EVA. The mold used for casting can be fabricated using a variety of methods. The choice of method used can be chosen based on the fabrication speed and can be limited by the smallest feature size of the mold, which is typically the width of the contacts of the solar cells. For example, if the contacts of the solar cells are on the order of several micrometers, ion milling and/or photolithographic techniques can be used to fabricate the mold. If the contacts are wide enough, computer numerical control (CNC) milling and/or 3D printing can be used to fabricate the mold. Although specific methods of fabricating a mold are discussed herein, a person having ordinary skill in the art would understand that fabrication of a mold can be achieved using any one of a number of machining methods.

A passivation layer can optionally be bonded (506) to the solar cell. A passivation layer is not necessary for the encapsulated solar cell to operate. However, in embodiments where the encapsulated volumes is gas-filled, degradation of the contacts and the solar cell can occur over time, when the solar cell is not chemically passivated. In many embodiments, a passivation layer can be bonded to the solar cell, covering the solar cell to prevent degradation. In some embodiments, the passivation layer is made of a resin polymer that can be poured over the solar cell and cured, creating a layer that covers and chemically passivates the solar cell. In further embodiments, the uncured polymer can be desiccated in a vacuum chamber to remove the air bubbles, which, if cured, can adversely affect the refraction of incident light. Passivation layers can be made of a variety of materials including but not limited to PDMS, PMMA, and EVA. Although specific methods of bonding the passivation layer are discussed, any one of a variety of methods can be used to bond the passivation layer.

The encapsulant layer can be attached (508) to the solar cell using any one of a number of methods. In many embodiments, the encapsulant layer can be attached to the solar cell using adhesives. In a variety of embodiments, the encapsulant layer can be affixed onto the solar cell using resin polymer as an adhesive mortar. In some embodiments, the encapsulant layer can be attached to the solar cell using mechanical pressure. In embodiments where there is a passivation layer made of a curable resin polymer, the encapsulant layer can be affixed during the curing step. For example, uncured resin polymer can be poured over the solar cell to begin the formation of a passivation layer. Before curing, an encapsulant layer can be pressed over the passivation layer. During the curing process, the encapsulant layer can be affixed to the solar cell. In further embodiments, the encapsulant layer and the passivation layer can be made of the same material.

Although FIG. 5 illustrates exemplary concepts and methods, a person having ordinary skill in the art would understand that the steps in constructing an encapsulated solar cell are not limited to only the steps and order as listed above and that any of a variety of methods for constructing encapsulant layers for solar cells containing with a negative relief pattern can be utilized as appropriate to the requirements of specific applications in accordance with embodiments of the invention.

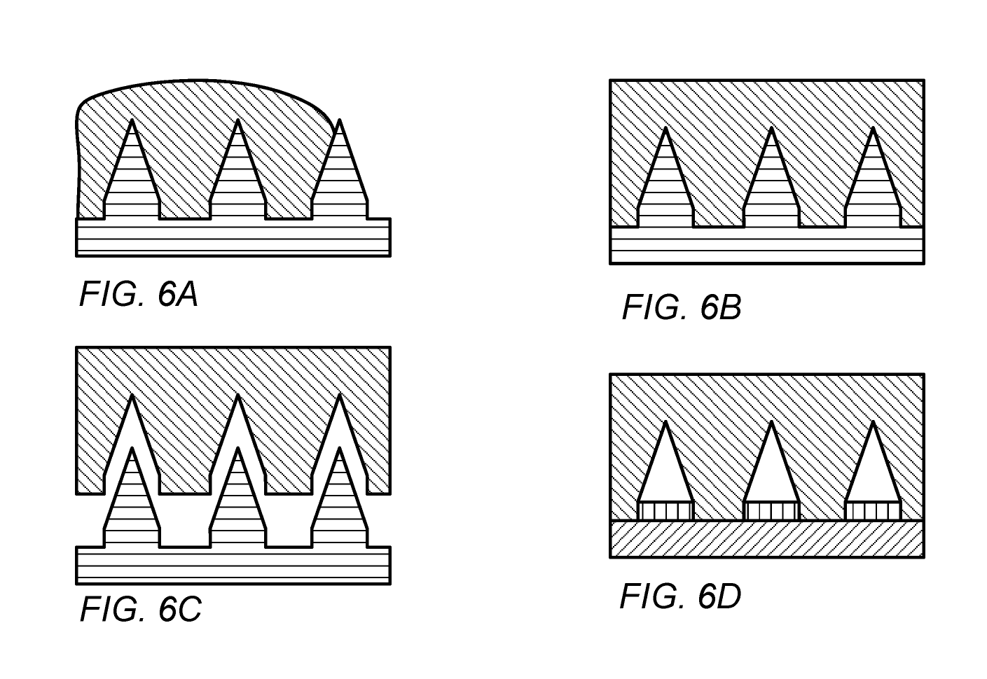

FIGS. 6A-6D conceptually illustrate the steps of fabricating an encapsulant layer and attaching it to a solar cell, forming an encapsulated solar cell. In many embodiments of the invention, the encapsulant layer can be fabricated using mold casting. Mold casting can be an inexpensive and quick method of fabrication for resin polymers. The casting method can include pouring uncured liquid polymer into a mold (FIG. 6A). A mold can be fabricated using any one of a number of methods such as those described above. Depending on the type of polymer used, the liquid polymer can be cured (FIG. 6B) using a variety of methods including but not limited to heat, freezing, and the use of a curing agent. Once cured, the cast encapsulant layer can be removed (FIG. 6C) and attached (FIG. 6D) to a solar cell. The encapsulant layer can be attached using any one of a number of methods such as those described above.

Although FIGS. 6A-6D illustrate exemplary methods for fabricating an encapsulant layer and attaching the encapsulant layer onto a solar cell, a person having ordinary skill in the art can readily appreciate that the steps in constructing an encapsulated solar cell is not limited to only the steps and order as depicted in FIGS. 6A-6D and that any of a variety of methods and fabrication steps can be utilized, such as (but not limited to) non-casting methods, as appropriate to the requirements of specific applications in accordance with a number of embodiments of the invention.

### Passivation Layers

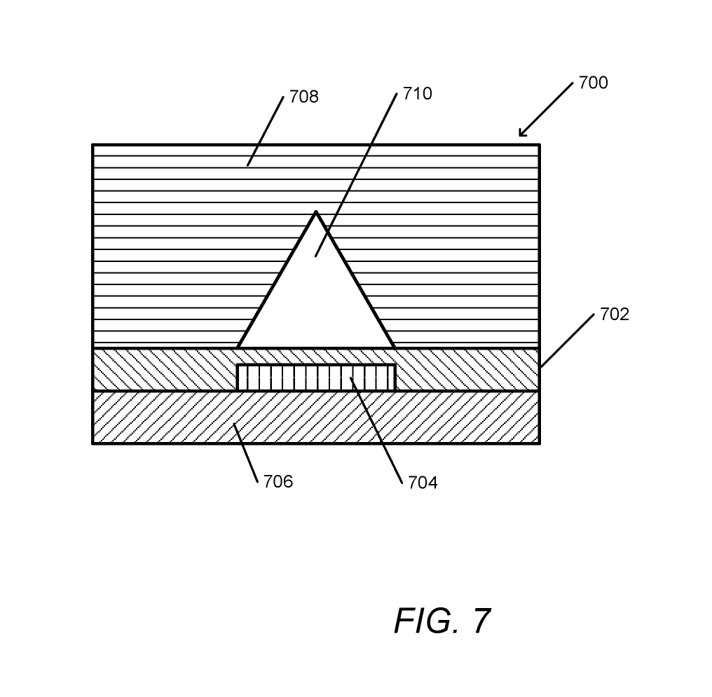

In some embodiments, an encapsulated solar cell can be constructed with an encapsulated volume containing a gas. The contained gas can be atmospheric gas, especially in cases where the encapsulant layer is gas permeable. The use of a gas-filled encapsulated volume can cause parts of the solar cell exposed to the gas to degrade over time. In several embodiments, this exposure can be diminished by covering the solar cell with a passivation layer. The passivation layer typically covers the entire front surface of the solar cell. In a number of embodiments, the encapsulant layer can be attached directly to the passivation layer. FIG. 7 conceptually illustrates an encapsulated solar cell with a passivation layer and a gas-filled encapsulated volume. As shown, the encapsulated solar cell 700 contains a passivation layer 702 covering a front contact 704 and a photoabsorbing substrate 706. The passivation layer 702 can be made of any one of a variety of materials capable of passivating the solar cell. Once the passivation layer 702 is bonded to the metal contact 704 and the photoabsorbing substrate 706, an encapsulant layer 708 containing a cavity can be attached to the passivated solar cell, interposing the passivation layer 702 between the encapsulant layer 708 and the front contact 704. In the illustrated embodiment, the encapsulant layer 708 contains a triangular shaped cavity, which forms an encapsulated volume 710 having a triangular cross section. The encapsulated volume 710 can be filled with atmospheric gas during the attachment of the encapsulant layer 708. In other embodiments, the encapsulated solar cell 700 is assembled in a controlled environment capable of forming an encapsulated volume 710 filled with a specific gas such as but not limited to an inert gas. The passivation layer 702 can be made of any one of a variety of materials such as but not limited to PDMS, PMMA, and EVA. In several embodiments, the passivation layer 702 can be made of the same material as the encapsulant layer 708.

Although various embodiments of solar cells including passivation layers are described above with reference to FIG. 7 illustrates an exemplary embodiment of an encapsulated solar cell, a person having ordinary skill in the art would understand that encapsulated solar cells having a gas-filled encapsulated volume are not limited to only the embodiment as depicted in FIG. 7 and that any number of constructions of an encapsulated solar cell having a gas-filled encapsulated volume can be utilized as appropriate to the requirements of specific applications in accordance with various embodiments of the invention.

### Infilling Encapsulated Volumes

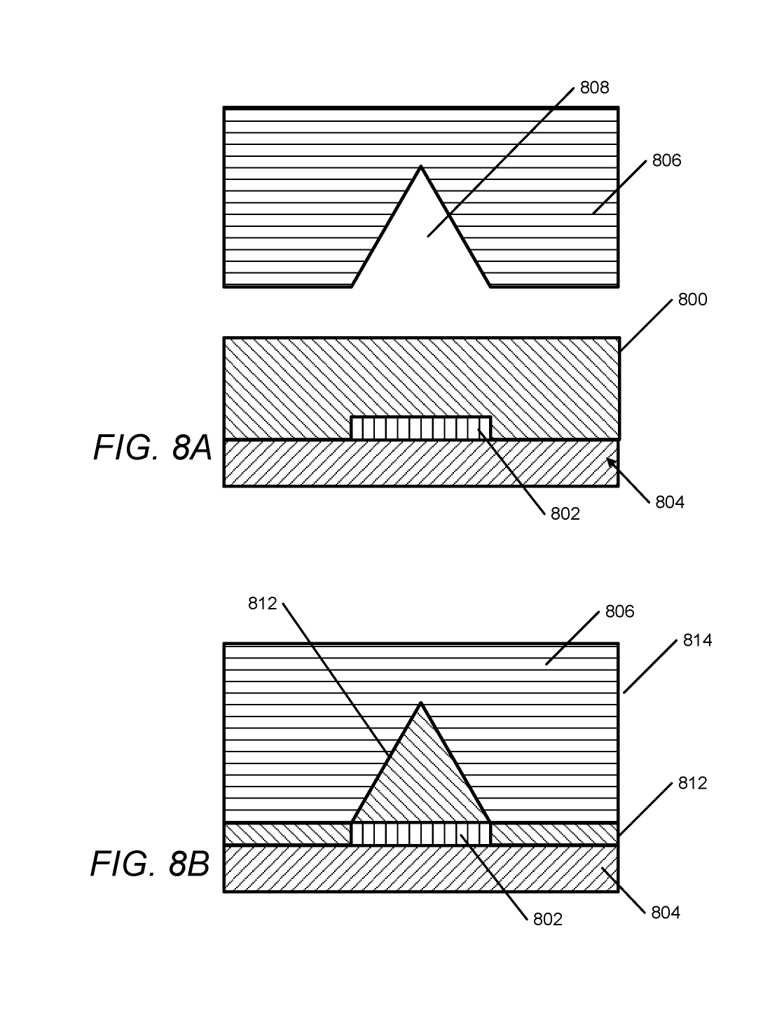

In many embodiments, an encapsulated solar cell can be constructed with an encapsulated volume containing an infill material. A method of constructing a solar cell in which the encapsulant layer contains encapsulated volumes filled with an infill material in accordance with an embodiment of the invention is illustrated in FIGS. 8A-8B. In the illustrated embodiment, an uncured amount of infill material 800 can be poured onto a conventional solar cell having a front contact 802 and a photoabsorbing substrate 804. The type of infill material 800 can be one of a variety of materials such as but not limited to PDMS, PMMA, and EVA. As long as the encapsulant layer 806 has a higher refractive index than the infill material 800, total internal reflection can occur. An encapsulant layer 806 containing a cavity 808 can be placed and pressed onto the infill material 800, filling up the cavity 808 with the infill material 800. In several embodiments, the encapsulant layer 806 does not contact the front contact 802 or the photoabsorbing substrate 804, leaving a layer of infill material 800 in between, which can act as a passivation layer. Once the infill material 800 is cured, the encapsulant layer 806 can be fixed in place, forming an encapsulated solar cell 814 having an encapsulated volume containing an infill material 816.

Although a variety of embodiments of solar cells incorporating encapsulant layers containing encapsulated volumes filled with a solid infill material are described above with respect to FIG. 8, any of a variety of techniques for manufacturing encapsulated solar cells having an encapsulated volume containing an infill material can be utilized as appropriate to the requirements of specific applications in accordance with various embodiments of the invention. For example, in many embodiments of the invention, the infill material can be spread into the cavities of the encapsulant layer, and the encapsulant layer can then be attached to the conventional solar cell using any one and/or a combination of methods including those described above.

### Construction of Encapsulated Solar Cells Using Sacrificial Structure

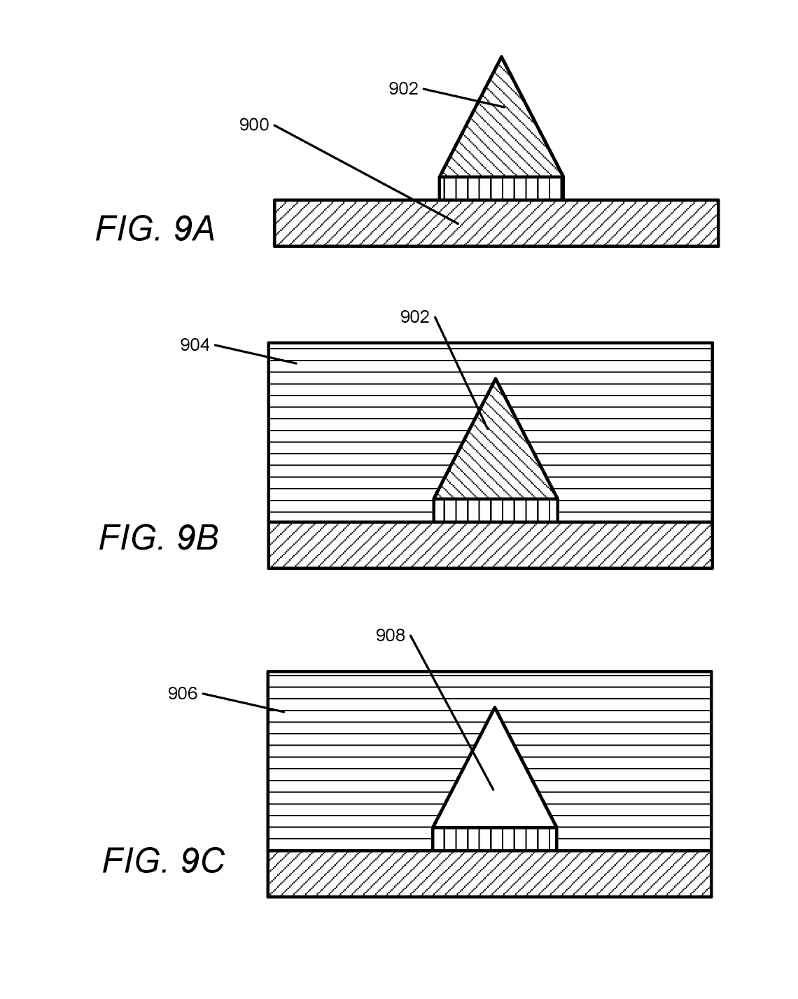

In many embodiments, an encapsulated solar cell can be constructed by fabricating an encapsulant layer by laying uncured encapsulant layer material over a formed sacrificial structure and then removing the sacrificial structure once the encapsulant layer is cured. A method for fabrication of encapsulated solar cell is illustrated in FIGS. 9A-9C. FIG. 9A depicts a conventional solar cell 900 with a sacrificial structure 902. The sacrificial structure 902 can be formed using any one and/or a combination of methods. In some embodiments, the sacrificial structure 902 can be fabricated using 3D printing. The sacrificial structure 902 can be made of any one and/or a combination of materials. Typically, the material is chosen for its ability to dissolve without adversely affecting the structure of the encapsulant layer. After the sacrificial structure 902 is formed, uncured encapsulant layer material 904 can be poured or screened over the entire solar cell 900. A curing process can be applied such as but not limited to applying heat and/or a curing agent. Once the encapsulant layer is cured 906, the sacrificial structure 902 can be removed, leaving behind an encapsulated volume 908. In many embodiments, the sacrificial structure can be removed by creating a hole through the encapsulant layer 906 and dissolving the sacrificial structure 902 using a solvent through access created by the hole. As can readily be appreciated, any process that removes the sacrificial structure to create encapsulated volumes that are voids within the encapsulant layer can be utilized as appropriate to the requirements of a given application in accordance with various embodiments of the invention. For example, many embodiments in accordance with the invention utilizes a sacrificial structure in combination with a passivation layer.

Although specific solar cells that use total internal reflection to direct light within the encapsulant away from front contacts and toward active regions of the solar cell and methods of manufacturing encapsulated solar cells are discussed above, many different types of encapsulated solar cells can be implemented in accordance with various embodiments of the invention. It is therefore to be understood that the present invention may be practiced in ways other than specifically described, without departing from the scope and spirit of the present invention. Thus, embodiments of the present invention should be considered in all respects as illustrative and not restrictive. Accordingly, the scope of the invention should be determined not by the embodiments illustrated, but by the appended claims and their equivalents.

What is claimed is:

1. An encapsulated solar cell comprising:
a photoabsorbing substrate;
a plurality of contacts formed on a front surface of the photoabsorbing substrate; and
an encapsulant layer comprising an outer surface and an inner surface defining a plurality of cavities, wherein:
the encapsulant layer is attached to the front surface of the photoabsorbing substrate so that:
the inner surface of the encapsulant layer is located between the front surface of the photoabsorbing substrate and the outer surface of the encapsulant layer;
the plurality of cavities defined by the inner surface of the encapsulant layer encapsulates a plurality of volumes between the inner surface of the encapsulant layer and the front surface of the photoabsorbing substrate; and
at least one of the encapsulated plurality of volumes is positioned to direct light within the encapsulant layer away from at least one of the plurality of contacts using refraction; and
the refractive index of the encapsulant layer is greater than the refractive index of at least one of the encapsulated plurality of volumes.

2. The encapsulated solar cell of claim 1, wherein the encapsulant layer is made from at least one material selected from the group consisting of:
polydimethylsiloxane; and ethylene-vinyl acetate.

3. The encapsulated solar cell of claim 1, wherein the encapsulant layer is attached to the front surface of the photoabsorbing substrate using an intermediary passivation layer such that the intermediary passivation layer covers the photoabsorbing substrate and the plurality of contacts.

4. The encapsulated solar cell of claim 3, wherein the intermediary passivation layer is made from at least one material selected from the group consisting of polydimethylsiloxane, polymethylmethacrylate, and ethylene-vinyl acetate.

5. The encapsulated solar cell of claim 3, wherein the encapsulated plurality of volumes comprises a gas.

6. The encapsulated solar cell of claim 1, wherein the encapsulated plurality of volumes comprises an infill material.

7. The encapsulated solar cell of claim 6, wherein the infill material is made from at least one material selected from the group consisting of polydimethylsiloxane, polymethylmethacrylate, and ethylene-vinyl acetate.

8. The encapsulated solar cell of claim 1, wherein each of the encapsulated plurality of volumes has a triangular cross section having a height h and a width w.

9. The encapsulated solar cell of claim 8, wherein the refractive index of the encapsulant layer is n and the refractive index of the encapsulated volume is m such that:
$$\frac{n}{m} \geq \sqrt{2} .$$

10. The encapsulated solar cell of claim 9, wherein the height h and the width w of the triangular cross section is such that:
$$\frac{h}{w} \geq \frac{1}{2 \sqrt{{( \frac{n}{m} )}^{2} - 1}} .$$

11. A method for manufacturing an encapsulated solar cell, the method comprising:
providing a solar cell comprising a photoabsorbing substrate and a plurality of contacts formed on the photoabsorbing substrate;
fabricating an encapsulant layer comprising an outer surface and an inner surface defining a plurality of cavities; and
attaching the encapsulant layer to the solar cell, wherein:
the inner surface of the encapsulant layer is located between the front surface of the photoabsorbing substrate and the outer surface of the encapsulant layer;
the plurality of cavities defined by the inner surface of the encapsulant layer encapsulates a plurality of volumes between the inner surface of the encapsulant layer and the front surface of the photoabsorbing substrate;
at least one of the encapsulated plurality of volumes is positioned to direct light within the encapsulant layer away from at least one of the plurality of contacts using refraction; and
the refractive index of the encapsulant layer is greater than the refractive index of at least one of the encapsulated plurality of volumes.

12. The method of claim 11, wherein the encapsulant layer is made from at least one material selected from the group consisting of: polydimethylsiloxane; and ethylene-vinyl acetate.

13. The method of claim 11, wherein the encapsulant layer is attached to the front surface of the photoabsorbing substrate using an intermediary passivation layer such that the intermediary passivation layer covers the photoabsorbing substrate and the plurality of contacts.

14. The method of claim 13, wherein the intermediary passivation layer is made from at least one material selected from the group consisting of polydimethylsiloxane, polymethylmethacrylate, and ethylene-vinyl acetate.

15. The method of claim 13, wherein the encapsulated plurality of volumes comprises a gas.

16. The method of claim 11, wherein the encapsulated plurality of volumes comprises an infill material.

17. The method of claim 16, wherein the infill material is made from at least one material selected from the group consisting of polydimethylsiloxane, polymethylmethacrylate, and ethylene-vinyl acetate.

18. The method of claim 11, wherein each of the encapsulated plurality of volumes has a triangular cross section having a height h and a width w.

19. The method of claim 18, wherein the refractive index of the encapsulant layer is n and the refractive index of the encapsulated volume is m such that:
$$\frac{n}{m} \geq \sqrt{2} .$$

20. The method of claim 19, wherein the height h and the width w of the triangular cross section is such that:
$$\frac{h}{w} \geq \frac{1}{2 \sqrt{{( \frac{n}{m} )}^{2} - 1}} .$$
